(19) United States
(12) Patent Application Publication
(10) Pub. No.: US 2026/0113879 A1
(43) Pub. Date: Apr. 23, 2026

(54) COOLING DISTRIBUTION UNIT WITH MODULAR SENSORS

(71) Applicant: LTI Holdings, Inc., Pleasanton, CA (US)

(72) Inventors: Steven J. Medeiros, Loudon, NH (US); Tristan G. Whiting, Watertown, MA (US); Peter D. Bennett, Hampton, NH (US)

(21) Appl. No.: 19/359,911

(22) Filed: Oct. 16, 2025

Related U.S. Application Data
(60) Provisional application No. 63/708,559, filed on Oct. 17, 2024.

(51) Int. Cl. H05K 7/20

(52) U.S. Cl. CPC H05K 7/20281; H05K 7/20263; H05K 7/20272

(57) ABSTRACT

A cooling distribution unit includes a primary closed loop configured to circulate a first fluid, a secondary closed loop configured to circulate a second fluid across electrical components to pick up heat from the electrical components, a heat exchanger configured to exchange heat between the second fluid and the first fluid such that a portion of the heat picked up from the electrical components is transferred from the second fluid to the first fluid, a modular sensor block including a plurality of sensors configured to produce output signals regarding the first fluid and the second fluid, and an electronic controller configured to provide power, operational control, and protection to the cooling distribution unit. The electronic controller is further configured to receive the output signals from the plurality of sensors, and generate an alert based on the received output signals.

### CROSS-REFERENCE TO RELATED APPLICATIONS

This application claims priority to U.S. Provisional Application No. 63/708,559, filed October 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU’s) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a primary closed loop configured to circulate a first fluid, a secondary closed loop configured to circulate a second fluid across one or more electrical components to pick up heat from the electrical components, a heat exchanger configured to exchange heat between the second fluid and the first fluid such that a portion of the heat picked up from the electrical components is transferred from the second fluid to the first fluid, a modular sensor block including a plurality of sensors configured to produce output signals regarding the first fluid and the second fluid, and an electronic controller configured to provide power, operational control, and protection to the cooling distribution unit. The electronic controller is further configured to receive the output signals from the plurality of sensors, and generate an alert based on the received output signals.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1.

FIG. 5 is a control system for the cooling distribution unit of FIG. 1.

### DETAILED DESCRIPTION

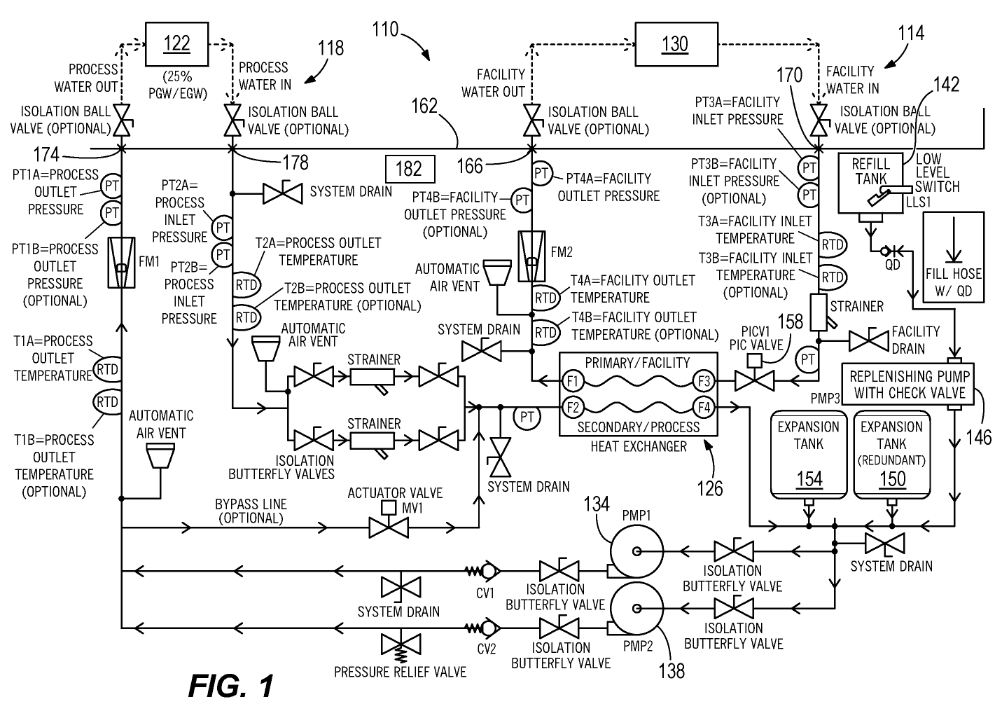

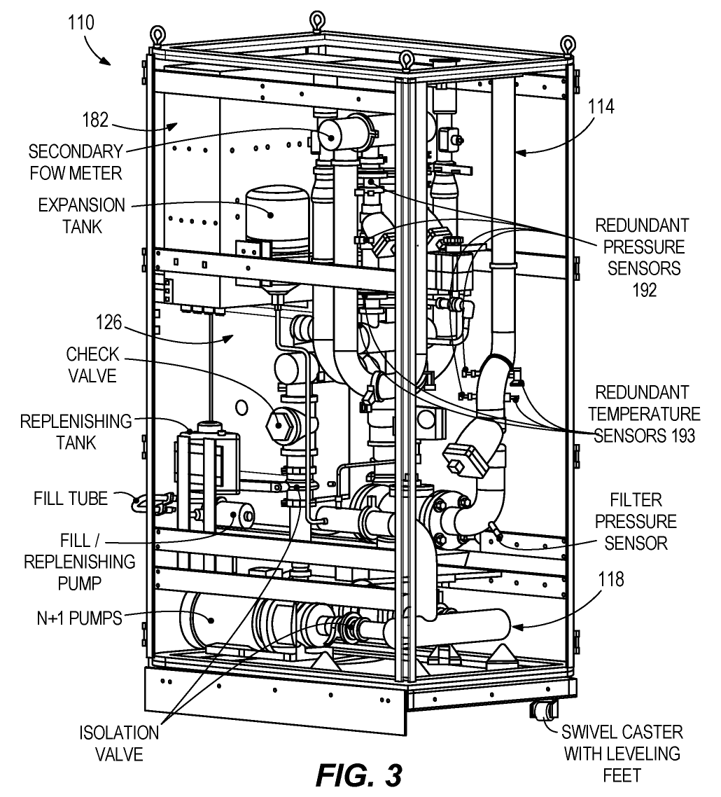

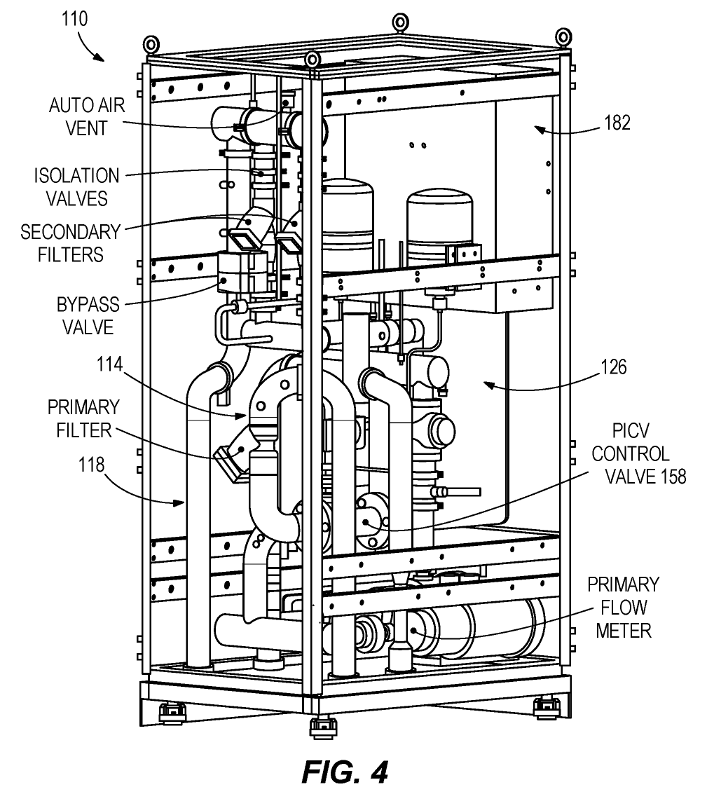

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

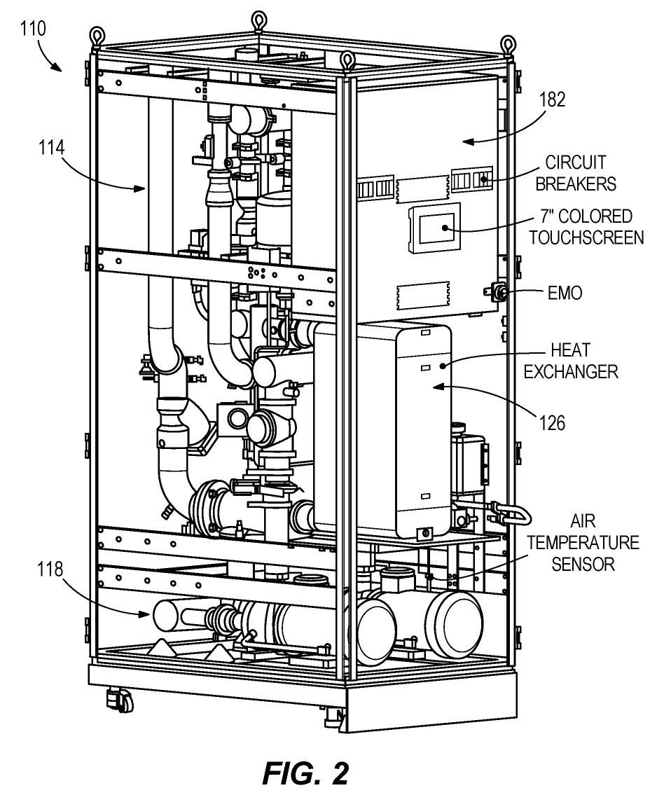

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop 118 may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG .1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/ or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50GPM, 100GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 includes one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, where the primary closed loop 114 enters, and where the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

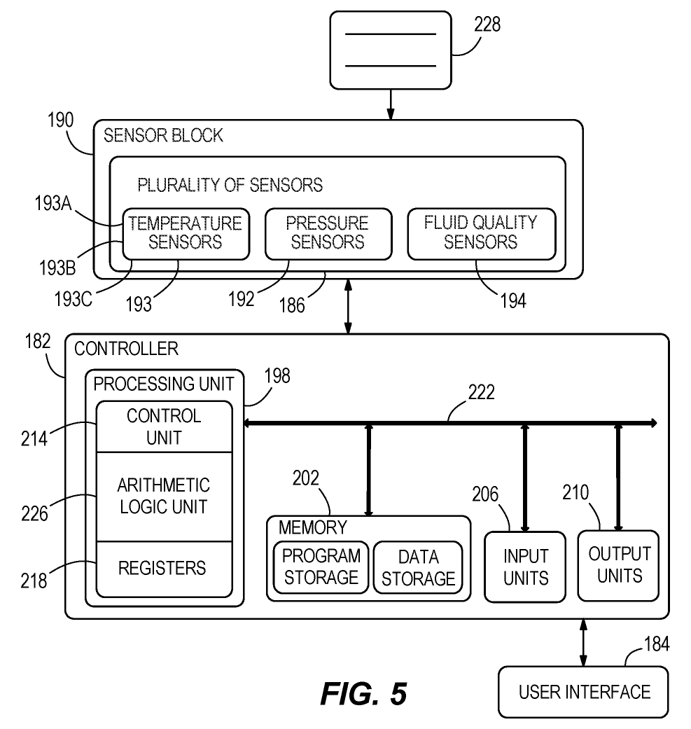

As illustrated in FIG. 5, in some examples, the cooling distribution unit 110 includes a plurality of sensors 186 that measure pressure, temperature, and/or other aspects of the system. In the illustrated example, the plurality of sensors 186 are positioned in at least one sensor block 190. The sensor block 190 may be a cube-shaped (or other-shaped) container configured to protect and house the plurality of sensors 186. In some examples, the sensor block 190 or blocks 190 are positioned generally at the first outlet 166, the first inlet 170, the second outlet 174, and/or the second inlet 178. In other examples, the sensors 186 are positioned individually (e.g., outside of any sensor block) at the first outlet 166, the first inlet 170, the second outlet 174, and/or the second inlet 178.

In some examples, one or more of the sensor blocks 190 is positioned within and incorporated into the heat exchanger 126 to save space within the cooling distribution unit 110. In other examples, one or more of the sensor blocks 190 is positioned within other components within the cooling distribution unit 110. Storing each of the plurality of sensors 186 in the sensor block 190 allows for modularity such that a user may place the sensor block 190 (e.g., modular sensor block) in a desired position within the cooling distribution unit 110. Accordingly, the sensor block 190 is configured to incorporate multiple sensors into one section rather than spreading out the plurality of sensors 186 throughout the cooling distribution unit 110. Therefore, the sensor block 190 is configured to allow for an efficient use of space and a standardized sensor assembly within the cooling distribution unit 110. Other examples include various locations within the cooling distribution unit 110 for the sensor block or blocks 190 and/or any individual sensors (e.g., pressure sensors, temperature sensors, fluid quality sensors, etc.).

With continued reference to FIG. 5, in some examples the plurality of sensors 186 may include redundant pressure sensors 192 and/or temperature sensors 193 (e.g., in the event one or more of the sensors fails or provides inaccurate readings). In the illustrated example, the cooling distribution unit 110 includes three (3) or more temperature sensors 193 (e.g., a first temperature sensor 193A, a second temperature sensor 193B, and a third temperature sensor 193C). Including multiple (e.g., at least three) temperature sensors 193A-C within the cooling distribution unit 110 allows for a user or electronic controller 182 to track the performance of each temperature sensor 193 to determine if one sensor is “inaccurate” or defective. More particularly, the electronic controller 182 may be configured to compare sensor readings or output signals of the temperature sensors 193A-C. For example, if the performance of the first temperature sensor 193A is identified to be substantially different than the performance of the second temperature sensor 193B and the third temperature sensor 193C, the first temperature sensor 193A is deemed to be inaccurate. In some examples, implementing three temperature sensors 193A-C may allow the user or controller 182 to quickly identify an inaccurate temperature sensor 193 by comparing the inaccurate temperature sensor 193 with the two remaining temperature sensors 193. In response to the controller 182 identifying an inaccurate temperature sensor 193, the controller 182 may be configured to generate an alert to inform the user that a temperature sensor 193A-C is inaccurate such that the inaccurate sensor may be replaced. Accordingly, the temperature sensors 193A-C are configured to allow for greater reliability of the sensors within the cooling distribution unit 110 and eliminate variability that may occur as a result of implementing only two temperature sensors 193. In the illustrated example, the temperature sensors 193 are rated for -50°C to 150°C, although other examples may include different ratings. In some examples, the cooling distribution unit 110 may similarly include three (3) or more pressure sensors 192. In some examples, the cooling distribution unit 110 additionally, or alternatively, includes two, three, or more redundant pressures sensors 192.

In the illustrated example, the plurality of sensors 186 are coupled (e.g., wired or wirelessly) to the controller 182 (FIGS. 2-5) or other device that receives signals regarding the pressure and temperature of the first fluid and the second fluid. In the illustrated example, the controller 182 is located on and/or within the housing 162, and may include a user interface 184 (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

The controller 182 includes a plurality of electrical and electronic components that provide power, operational control, and protection to the components and modules within the controller 182 and/or the cooling distribution unit 110. For example, the controller 182 includes, among other things, a processing unit 198 (e.g., a microprocessor, a microcontroller, or another suitable programmable device), a memory 202, input units 206, and output units 210. The processing unit 198 includes, among other things, a control unit 214, an arithmetic logic unit (“ALU”) 226, and a plurality of registers 218 (shown as a group of registers in FIG. 5) and is implemented using a known computer architecture (e.g., a modified Harvard architecture, a von Neumann architecture, etc.). The processing unit 198, the memory 202, the input units 206, and the output units 210, as well as the various modules or circuits connected to the controller 182 are connected by one or more control and/or data buses (e.g., common bus 222). The control and/or data buses are shown generally in FIG. 5 for illustrative purposes.

The memory 202 may be a non-transitory computer readable medium and include, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 198 is connected to the memory 202 and executes software instructions that are capable of being stored in a RAM of the memory 202 (e.g., during execution), a ROM of the memory 202 (e.g., on a generally permanent basis), or another non-transitory computer readable medium such as another memory or a disc. Software included in the implementation of the cooling distribution unit 110 can be stored in the memory 202 of the controller 182. The software includes, for example, firmware, one or more applications, program data, filters, rules, one or more program modules, and other executable instructions. The controller 182 is configured to retrieve from the memory 202 and execute, among other things, instructions related to the control processes and methods described herein. In other constructions, the controller 182 includes additional, fewer, or different components.

With continued reference to FIG. 5, the plurality of sensors 186 may further include a plurality of fluid quality sensors 194 configured to sense a quality of the first fluid and/or the second fluid. The sensors 194 may produce output signals indicative of the quality. In the illustrated example, the fluid quality sensors 194 are optional and may be added and removed by the user. Accordingly, the fluid quality sensors 194 are configured for modularity, thereby allowing the user to quickly remove and add the fluid quality sensors 194 to the sensor block 190. In alternate examples, the fluid quality sensors 194 may be permanent fixtures within the cooling distribution unit 110. In yet other examples, the fluid quality sensors 194 may not be included within the sensor block 190 and may instead be positioned within or adjacent to any other appropriate component of the cooling distribution unit 110. In some examples, a plurality of ports 228 for sampling water quality may be included within the cooling distribution unit 110. The plurality of ports 228 may be in communication with the fluid quality sensors 194 to allow for sampling of fluid to be sensed by the fluid quality sensors 194. In yet other examples, the plurality of ports 228 for sampling fluid may be included external to the cooling distribution unit 110.

In some examples, the fluid quality sensors 194 are coupled with the controller 182 such that the controller 182 may read the fluid quality sensors 194 and monitor the quality of the fluid circulating within the cooling distribution unit 110, the primary closed loop 114, and/or the secondary closed loop 118. In response to poor fluid quality, the controller 182 may be configured to generate an alert to inform the user that the fluid quality is poor. Implementing the fluid quality sensors 194 provides various advantages. For example, monitoring the quality of the fluid circulating within the cooling distribution unit 110 allows the user or controller 182 to know when the fluid quality is poor and replace the fluid. Poor water quality may impact performance of the pumps 134, 138 over time. For example, poor water quality may increase uptime of the cooling distribution unit 110. Therefore, incorporating fluid quality sensors 194 may prevent poor performance of the cooling distribution unit 110.

In the illustrated example, the cooling distribution unit 110 has an overall dimension of 31.5” by 47.4” by 84.5”, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550kW (at 4ºC approach temperature difference) and 1100kW (at 8ºC approach temperature difference). Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a primary closed loop configured to circulate a first fluid;
a secondary closed loop configured to circulate a second fluid across electrical components to pick up heat from the electrical components;
a heat exchanger configured to exchange heat between the second fluid and the first fluid such that a portion of the heat picked up from the electrical components is transferred from the second fluid to the first fluid;
a modular sensor block including a plurality of sensors configured to produce output signals regarding the first fluid and the second fluid; and
an electronic controller configured to provide power, operational control, and protection to the cooling distribution unit, the electronic controller further configured to:
receive the output signals from the plurality of sensors, and
generate an alert based on the received output signals.

2. The cooling distribution unit of claim 1, wherein the modular sensor block is positioned within the heat exchanger.

3. The cooling distribution unit of claim 1, wherein the plurality of sensors includes one or more pressure sensors and one or more temperature sensors.

4. The cooling distribution unit of claim 3, wherein the one or more temperature sensors include a first temperature sensor, a second temperature sensor, and a third temperature sensor.

5. The cooling distribution unit of claim 4, wherein the electronic controller is further configured to compare output signals of the first temperature sensor, the second temperature sensor, and the third temperature sensor to determine an inaccurate sensor.

6. The cooling distribution unit of claim 5, wherein in response to the electronic controller determining that an output signal of the first temperature sensor is different from the second temperature sensor and the third temperature sensor, the electronic controller is configured to identify the first temperature sensor as inaccurate.

7. The cooling distribution unit of claim 6, wherein the alert is configured to inform a user that the first temperature sensor is inaccurate.

8. The cooling distribution unit of claim 1, wherein the plurality of sensors includes a plurality of fluid quality sensors.

9. The cooling distribution unit of claim 8, wherein the output signals are an indication of a quality of the first fluid or second fluid.

10. The cooling distribution unit of claim 9, wherein the alert is configured to inform a user that the quality of the first fluid or second fluid is poor.

11. The cooling distribution unit of claim 8, wherein the plurality of sensors further includes one or more pressure sensors and one or more temperature sensors.

12. The cooling distribution unit of claim 11, wherein the one or more temperature sensors include a first temperature sensor, a second temperature sensor, and a third temperature sensor.

13. The cooling distribution unit of claim 12, wherein the electronic controller is further configured to compare output signals of the first temperature sensor, the second temperature sensor, and the third temperature sensor to determine an inaccurate sensor.

14. The cooling distribution unit of claim 13, wherein in response to the electronic controller determining that an output signal of the first temperature sensor is different from the second temperature sensor and the third temperature sensor, the electronic controller is configured to identify the first temperature sensor as inaccurate.

15. The cooling distribution unit of claim 14, wherein the alert is configured to inform a user that the first temperature sensor is inaccurate.

16. The cooling distribution unit of claim 1, wherein the cooling distribution unit includes a housing, wherein the primary closed loop is configured to exit and enter the housing, and wherein the secondary closed loop is also configured to exit and enter the housing.

17. The cooling distribution unit of claim 16, wherein the housing includes a first outlet where the primary closed loop exits the housing, and the first fluid is sent to a cooling structure, and wherein the housing also includes a first inlet, where the primary closed loop enters the housing, and where the first fluid is then directed to the heat exchanger.

18. The cooling distribution unit of claim 17, wherein the housing includes a second outlet where the secondary closed loop exits the housing and the second fluid is sent to the electrical components, and a second inlet where the second fluid enters the housing and is directed to the heat exchanger.

19. The cooling distribution unit of claim 18, wherein the modular sensor block is positioned generally at either of the first outlet, the first inlet, the second outlet, the second inlet, or the heat exchanger.

20. The cooling distribution unit of claim 19, wherein the modular sensor block is a first modular sensor block, wherein the cooling distribution unit includes a plurality of modular sensor blocks positioned generally at one or more of the first outlet, the first inlet, the second outlet, the second inlet, or the heat exchanger.
